(19) United States
(12) Patent Application Publication
(10) Pub. No.: US 2025/0342300 A1
(43) Pub. Date: Nov. 6, 2025

(54) Device for processing data by learning, method, program and corresponding system

(71) Applicants: UNIVERSITE DE TOULON, LA GARDE (FR); CENTRE NATIONAL DE LA RECHERCHE SCIENTIFIQUE, PARIS (FR)

(72) Inventors: Valentin Gies, Toulon (FR); Sebastian Marzetti, Toulon (FR); Valentin Barchasz, Brignoles (FR)

(21) Appl. No.: 18/873,042

(22) PCT Filed: Jun. 5, 2023
(86) PCT No.: PCT/EP2023/065015

§ 371 Date: Dec. 9, 2024

(30) Foreign Application Priority Data
Jun. 10, 2022 (FR) 2205623

(51) Int. Cl. G06F 30/38; G06F 30/337; G06F 30/373; G06N 3/084

(52) U.S. Cl. CPC G06F 30/38; G06F 30/337; G06F 30/373; G06N 3/084

(57) ABSTRACT

A method for determining implementation parameters of an electronic circuit configured to process an input signal. The electronic circuit includes an analog portion having a plurality of parameterisable analog primitives and a digital portion having a plurality of parameterisable digital primitives. The digital portion is coupled to the analog portion by at least one analog-digital converter and/or at least one analog comparator with or without hysteresis. The method includes a phase of joint learning of the parameters of the plurality of parameterisable analog primitives and of the parameters of the plurality of parameterisable digital primitives.

### TECHNICAL FIELD

The present invention relates to the field of signal processing. More particularly, the invention relates to the field of signal processing in a constrained system, in particular in a system constrained in terms of energy consumption.

### PRIOR ART

Recent years have seen the revolution of the Internet of Things (IoT) and that of remote data processing (cloud computing). The number of IoT devices continues to grow annually and it is expected that at least 30 billion devices will be operational worldwide within a few years. Most of these systems transmit raw data to process them remotely. Often, remote processing methods use energy-intensive Artificial Intelligence (AI) algorithms: for example, the Convolutional Neural Network (CNN) that can have tens of thousands of neurons and a few million connections. Since most of the energy consumption is dedicated to data transmission (and not for processing), the overall scheme for remote data management and processing is very energy-intensive.

It is therefore necessary to increase the semantic level of the information obtained locally within IoT devices. For example, in most cases of thermo-industrial monitoring, the temperature can normally be constant: there is no need to transfer this low-level data because the relevant events only occur when there is a significant change in the measurement. The detection of this event should be performed locally, by increasing the semantic level of the signal to be transferred remotely. In this case, an alert can be sent remotely, which avoids having to transfer low-level raw data. However, this need for local processing raises a problem: how to implement complex processing and in particular processing based on artificial intelligence, in embedded IoT type architectures? Indeed, avoiding the permanent transfer of all sensor data implies their local processing. This is necessary and was highlighted in the European Commission's text on communication and digital guidelines, setting a target of 80% of data processing performed locally.

However, this raises multiple technical problems: local data processing must be adapted to the hardware available in embedded systems, in particular in terms of memory and computing power. Moreover, the introduction of signal processing (or artificial intelligence) increases the average power consumption, especially if advanced algorithms such as deep learning are used, even if it also reduces the power consumption due to data transmission. Since the battery capacity is limited in many industrial or daily life products, the use of a significant portion of energy for artificial intelligence tasks also results in a reduction in the service life of the product in non-rechargeable applications, or the need to recharge the battery or use an external power supply.

Therefore, there is a need for a solution to have autonomous devices allowing processing signals locally, with a significant reduction in the energy consumption of such devices. The disclosed technique improves the situation.

### SUMMARY OF THE INVENTION

The disclosed technique was designed with these prior art issues in mind. The proposed technique allows the implementation of an embedded artificial intelligence with minimal energy cost. A mixed processing technique (analogue-digital) is used to replace convolutional neural network type solutions, while learning the parameters of the global model, these parameters comprising analogue parameters and digital parameters, from a labelled database. This mixed architecture is called primitive neural network (PNN).

More particularly, the present invention relates to a method for determining implementation parameters of an electronic circuit intended to be implemented by a computer or a data processor, said electronic circuit being configured to perform the processing of an input signal, the electronic circuit comprising an analogue portion comprising a plurality of parameterisable analogue primitives and a digital portion comprising a plurality of parameterisable digital primitives, the implementation parameters of the electronic circuit including parameters of the plurality of parameterisable analogue primitives and parameters of the plurality of parameterisable digital primitives, the digital portion being coupled to the analogue portion via at least one analogue-digital converter and/or at least one analogue comparator with or without hysteresis. Such a method comprises a phase of learning said parameters of the plurality of parameterisable analogue primitives and said parameters of the plurality of parameterisable digital primitives, said learning phase being joint with the parameters of the plurality of parameterisable analogue primitives and with the parameters of the plurality of parameterisable digital primitives.

Thus, it is possible to parameterise the entire electronic circuit with values that have been the subject of a prior learning, and therefore to adapt the electronic circuit as needed, in particular in terms of reducing the consumed energy.

According to a particular feature, the learning phase comprises at least one iteration of the following steps, performed using a labelled signal learning database:
loading of the current parameters of the plurality of parameterisable analogue primitives and the plurality of parameterisable digital primitives;
extraction, by the analogue portion, depending on the current parameters of the plurality of analogue primitives, of time information from the input signals and/or of frequency information from these same signals. The latter may correspond to a plurality of moments of the signals of the learning database;
Construction, using the previously extracted time and/or frequency information, of an intermediate data structure. This intermediate data structure may be formed by the juxtaposition of the information extracted by the analogue portion from the signals of the learning database; this structure is for example a tensor.
classification, by the digital portion, depending on the current parameters of the plurality of digital primitives, and from the intermediate data structure, of the plurality of detected events, delivering a plurality of portions of classified signals;
calculation, from the plurality of portions of classified signals, of a classification error rate (Err);
correction of the current parameters of the plurality of parameterisable analogue primitives and of the plurality of parameterisable digital primitives depending on the error rate (Err).

According to a particular feature, the learning phase ends when the classification error rate (Err) is lower than a predetermined threshold and/or when a target power consumption, in operational operation, of said electronic circuit is reached.

According to a particular feature, the step of correcting the current parameters of the plurality of parameterisable analogue primitives and the plurality of parameterisable digital primitives comprises at least one iteration of the following optimisation sequence: optimisation of the digital portion by backpropagation, then optimisation of the analogue portion by iterative digital simulation methods. According to a particular feature, the digital portion comprises at least one neural network adapted to classify the signals received via analogue-digital converters and in that the parameters of the plurality of parameterisable digital primitives comprise at least weights and biases of said neural network.

According to a particular feature, the digital portion is, by default, on standby.

According to a particular feature, the analogue portion comprises at least one band-pass filter, said band-pass filter allowing identifying frequencies of interest and in that the parameters of the plurality of parameterisable analogue primitives comprise at least cut-off frequencies of said band-pass filter and in that the analogue portion comprises a plurality of trigger nodes for waking up said digital portion based on an identification of said frequencies of interest.

According to another aspect, the present invention also relates to an electronic circuit configured to perform the processing of an input signal according to the method for determining implementation parameters of said electronic circuit, said electronic circuit comprising an analogue portion and a digital portion, the digital portion being coupled to the analogue portion via one or several analogue-digital converters, and/or analogue comparator with or without hysteresis. In this electronic circuit, the analogue portion comprises a plurality of analogue primitives parameterised according to a first set of parameters and in that the digital portion comprises a plurality of digital primitives parameterised according to a second set of parameters, said first and said second sets of parameters belonging to the implementation parameters of said electronic circuit, said first and said second sets having been the subject of joint learning according to the previously presented method.

According to a particular feature, the plurality of parameterisable analogue primitives comprises analogue primitives belonging to the group comprising: passive and/or active filters, envelope detectors, multipliers, operational amplifier assemblies, diodes, analogue convolutions, integrators, derivators, delay.

According to a particular feature, the analogue portion of the electronic circuit is divided into a first part, called signal preprocessing part and a second part called moment extraction part, the output of the signal preprocessing part being connected to the input of the moment extraction part, the output of the moment extraction part being directly connected using at least one analogue-digital converter and/or an analogue comparator.

According to another aspect, the present invention also relates to the use of an electronic circuit configured to perform the processing of an input signal according to the method for determining implementation parameters of said electronic circuit, said electronic circuit comprising an analogue portion and a digital portion, the digital portion being coupled to the analogue portion via at least one analogue-digital converter or at least one analogue comparator, the analogue portion comprising a plurality of analogue primitives parameterisable according to a first set of parameters and the digital portion comprising a plurality of digital primitives parameterisable according to a second set of parameters. This use is remarkable in that it comprises a step of loading the first and second sets of parameters having been the subject of joint learning according to the previously presented method. According to a preferred implementation, the learning can be controlled/executed by a program, implemented within a processor, in order to control in particular the convergence of the learning parameters. The different steps of the methods according to the present disclosure are implemented by one or more software or computer programs, comprising software instructions intended to be executed by a data processor of an execution terminal according to the present technique and being designed to control the execution of the different steps of the methods, implemented at a communication terminal, a remote server and/or a blockchain, within the framework of a distribution of the processing to be carried out and determined by a scripted source code or a compiled code.

Consequently, the present technique also targets programmes that can be executed by a computer or by a data processor, these programmes including instructions to control the execution of steps of the method such as mentioned above.

A programme may use any programming language, and be in the form of source code, object code, or byte code between source code and object code, such as in a partially compiled form, or in any other desirable form.

The present technique also targets an information medium that can be read by a data processor, and including instructions of a programme such as mentioned above.

The information medium may be any entity or terminal capable of storing the programme. For example, the medium may include a storage means, such as a ROM, for example a CD ROM or a microelectronic circuit ROM, or also a magnetic recording means, for example a mobile medium (memory card) or a hard drive or an SSD.

On the other hand, the information medium may be a transmissible medium such as an electrical or optical signal, which may be routed via an electrical or optical cable, by radio or by other means. The programme according to the present technique may in particular be downloaded on an Internet type network.

Alternatively, the information medium may be an integrated circuit in which the program is incorporated, the circuit being suitable for executing or for being used in the execution of the method in question.

According to an embodiment, the present technique is implemented by means of software and/or hardware components. In this regard, the term “module” may correspond in this document to a software component as well as to a hardware component or to a set of software and hardware components.

A software component corresponds to one or more computer programmes, one or more subprogrammes of a programme, or more generally to any element of a programme or of software capable of implementing a function or a set of functions, according to what is described below for the module concerned. Such a software component is executed by a data processor of a physical entity (terminal, server, gateway, set-top-box, router, etc.) and is capable of accessing the hardware resources of this physical entity (memories, recording media, communication bus, input/output electronic cards, user interfaces, etc.).

In the same manner, a hardware component corresponds to any element of a hardware assembly capable of implementing a function or a set of functions, according to what is described below for the module concerned. This may concern a hardware component that can be programmed or with an integrated processor for executing software, for example an integrated circuit, a chip card, a memory card, an electronic card for executing firmware, etc.

Each component of the system described above of course implements its own software modules.

The various embodiments mentioned above can be combined with one another to implement the present technique.

### BRIEF DESCRIPTION OF THE FIGURES

Other aims, features and advantages of the disclosure will become clearer on reading the following description, which is given by way of a simple illustrative and non-limiting example, in relation to the figures, including:

FIG. 1 represents the general architecture of the network according to the present disclosure;

FIG. 2 illustrates the different digital and analogue primitives of the disclosure;

FIG. 3 is an example of the structure of the analogue portion of the network according to the disclosure;

FIG. 4 illustrates a one-dimensional signal before manual labelling;

FIG. 5 represents the one-dimensional signal of FIG. 4 after manual labelling;

FIG. 6 illustrates the training of the network with the input labelled data and the intermediate data generated by the analogue portion;

FIG. 7 illustrates the training of the network with the input labelled data and the sub-data generated by the analogue portion. Optimising the parameters of the analogue portion to start filtering out data that are not part of the targets;

FIG. 8 illustrates a parameterisable analogue primitive

FIG. 9 illustrates a parameterisable analogue primitive°;

FIG. 10 Illustrates a circuit according to the present disclosure;

FIG. 11 illustrates the architecture of a microcontroller according to the present disclosure;

FIG. 12 illustrates a portion of the input signal database and the corresponding labels;

FIG. 13 illustrates a network comprising three primitives;

FIG. 14 illustrates the convergence towards the target frequencies;

FIG. 15 shows three examples of the labelled raw data from the pressure sensor;

FIG. 16 shows an interface for constructing the primitive network;

FIG. 17 shows the outputs of several primitives;

FIG. 18 illustrates a first primitive network;

FIG. 19 illustrates a complete primitive network;

FIG. 20 illustrates a three-layer neural network, connectable to the complete primitive network of FIG. 19;

FIG. 21 illustrates a three-layer neural network, connectable to the complete primitive network of FIG. 19;

FIG. 22 Illustrates the parameter learning method according to an example.

### DETAILED DESCRIPTION

### Reminder of the Principles

The same elements bear the same reference signs in the various figures. In particular, the structural and/or functional elements that are common to the various exemplary embodiments can have the same reference signs and can have identical structural, dimensional and material properties. For the purposes of clarity, only the steps and elements that are useful for understanding the described exemplary embodiments are shown and described in detail. In particular, circuits for generating a signal and for controlling the frequency and intensity of this signal, as well as circuits for controlling and receiving values supplied by the sensors, are not described in detail, the exemplary embodiments described being compatible with usual such circuits. Unless otherwise specified, when reference is made to two elements being connected to each other, this means directly connected without intermediate elements other than conductors, and when reference is made to two elements that are linked or coupled together, this means that these two elements can be connected or be linked or coupled by means of one or more other elements. In the description which follows, when reference is made to absolute position qualifiers, such as the terms “front”, “rear”, “top”, “bottom, “left”, “right”, etc., or relative position qualifiers, such as the terms “above”, “below”, “upper”, “lower”, etc., or to orientation qualifiers, such as the terms “horizontal”, “vertical”, etc., reference is made unless otherwise specified to the orientation of the figures. Unless otherwise specified, the expressions “around”, “approximately”, “substantially”, and “in the range of” mean to within 10%, preferably to within 5%.

As previously explained, the disclosure relates, in a first aspect, to a device comprising an electronic circuit which comprises an analogue portion and a digital portion. The analogue portion is remarkable in that it comprises parameterisable functionalities (FPAA, FPMA). This analogue portion comprises a plurality of potentially usable functionalities (filters in particular), called “features” or “primitives”. These functionalities are independently activatable and parameterisable such that the power consumption thereof is limited to the uses made therefrom. The potential number of implementable parameterisable functionalities essentially depends on the complexity of the analogue portion. The circuit also comprises a digital portion. This digital portion is interfaced with the analogue portion via analogue-digital converters. The digital portion, for its part, comprises in particular an electronic decision-making circuit (of the artificial neural network or expert system type, for example) which is digitally implanted. When it is a neural network, it typically includes a few hundred or more neurons depending on the intended application and the intended power consumption.

In such an electronic circuit, according to the present, the input signals are therefore processed using a mixed architecture in which the analogue portion is implemented to perform a first series of data processing (processing of higher frequency signals, extraction of moments, etc.) and this data obtained from the analogue input signals is provided to the neural network, on the digital portion for processing at lower frequencies and obtaining results (for example classifications of the input signals). This architecture allows meeting the needs of energy consumption limitations. A significant feature of the disclosure relates to the general configuration of the proposed electronic circuit: the learning of the analogue and digital parameters of such a circuit is carried out globally and comprises both the learning of the parameters of the digital neural network and, at the same time, the learning of the parameters of the primitives of the analogue portion. Thus, the circuit can be used in many situations and can have a single certification, which also reduces the implementation costs thereof.

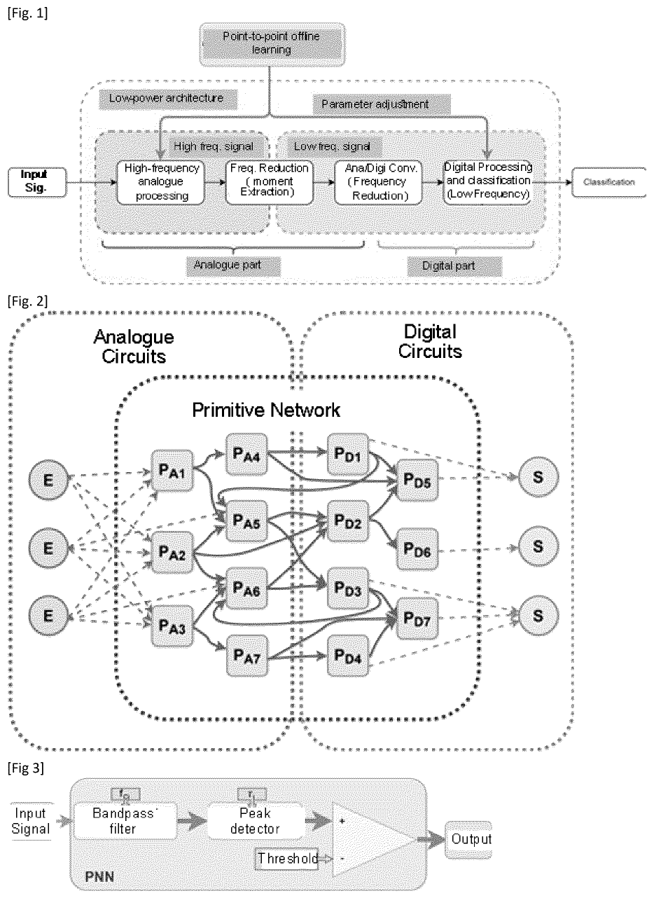

In other words, the primitive network constitutes a mixed (analogue and digital) electronic architecture intended to implement embedded artificial intelligence for decision-making or pattern identification, by targeting ultra-low-power applications with joint optimisation of energy consumption and classification accuracy, with the following particularities:
The proposed technique differs from the other conventional architectures for embedded AI comprising a fixed analogue front-end circuit and a digital portion implementing neural networks: the proposed technique allows a joint end-to-end learning of the parameters of the analogue and digital parts (FIG. 1).
The proposed technique allows obtaining ultra-low-power systems and networks of limited size.
The architecture is divided into two distinct portions (analogue/digital) (FIG. 1) corresponding to very different signal frequencies in order to optimise the energy consumption. High-frequency processing is done in analogue, resulting in a gain of a factor of 100 in power relative to digital, while low-frequency processing is done in digital. The transition from one to the other is done using one or more analogue-digital converters using data from moment extractors (these allow drastically reducing the useful frequency of the signal (for example filters, averagers, peak detector)), one or more analogue-digital converters allowing acquiring portions of limited size of the high-frequency input signals or processed by the analogue network, the use of digital rising or falling edges from comparators with or without analogue hysteresis.
The analogue portion is composed of analogue primitives: passive and/or active filters, envelope detectors, multipliers, operational amplifier assemblies (adders, subtractors, phase shifters, etc.), diodes, analog convolutions (wavelets for example). The concrete implementation is similar to an FPAA, with a structure successively coupling programmable analogue input points ending with moment extractors, analogue-digital converters (ADCs), comparators and a digital processor optimised for the neural calculations.
The architecture brings model diversity to the paradigm of conventional neural networks/CNNs: learning can be performed on something other than neurons (FIG. 2: “E”: input, “PA1” to “PA7” (analogue primitives), “PD1” to “PD7” (digital primitives) and “S” (output), and in particular on primitives that cannot be easily modelled by neurons, for example a multiplier, a filter, a correlator between signals or a time delay (“PA1” to “PA7”).
The evaluation criterion for learning depends on the quality of classification, but also on the power consumed by the network and the complexity of the network at the electronic level.
The manner of learning is particular because of the presence of moment extraction operators that break or limit the possibility of doing gradient backpropagation. The optimisation technique is therefore different from that of conventional learning: a learning process optimising the analogue portion by gradient descent is iterate, after having previously optimised the digital network at each step of the analogue gradient calculation. To do this, at each step of the optimisation:
The analogue portion of the network is fixed. For example, the circuit in FIG. 13;
From a labelled data set (once and for all), we generate an intermediate labelled training data set at the output of the analogue part and ADC/comparator (and therefore after the moment extraction operations), and this automatically.
This intermediate training data set, dependent on the analogue operations, is used for the conventional learning of the network of the digital portion.

Once this learning of the digital portion is performed, the process is reiterated by varying the parameters of the analogue portion, so as to be able to calculate a gradient depending on the parameters of the analogue portion so as to optimise them. The global analogue/digital optimisation is potentially algorithmically expensive, but it remains calculable given that applications implemented in architectures with limited capacities are targeted. In addition, since this optimisation is carried out “offline”, the computing resources do not pose any difficulties at this stage.
In addition, thanks to this architecture, it is possible, in learning, to determine the order of the primitives automatically (insofar as the networks are ultimately of limited size and therefore limited combinatorics).

### General Description of the Learning Methodology

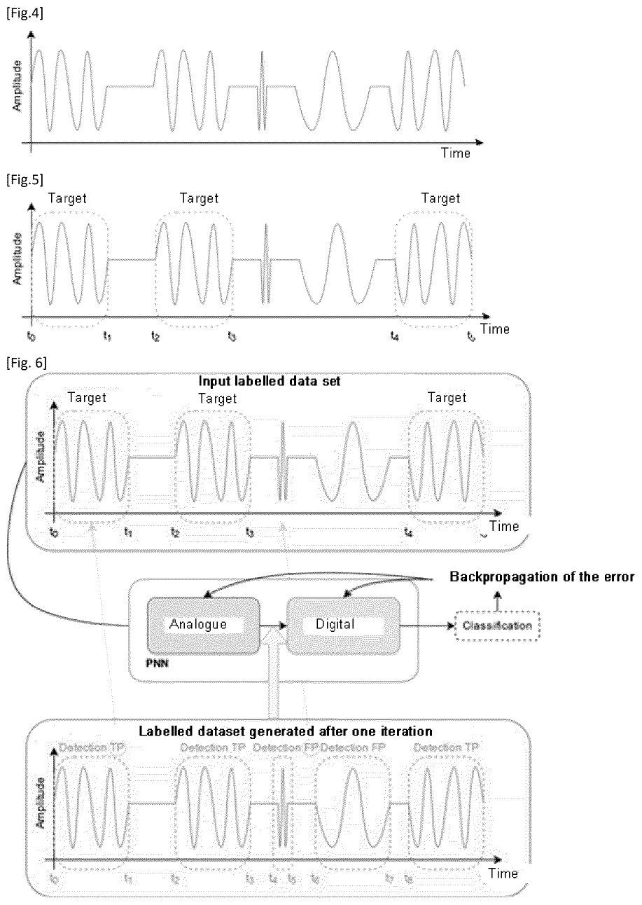

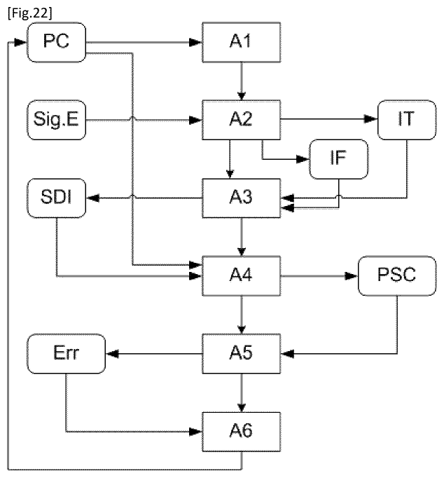

The learning as well as the processing of the primitive network is generally presented in this section, in relation to FIG. 22. In this example, the method for determining implementation parameters of an electronic circuit, the learning phase comprises at least one iteration of the following steps, carried out using a learning database of labelled signals:
Loading (A1) of current parameters (PC) of the plurality of parameterisable analogue primitives and of the plurality of parameterisable digital primitives;
Extraction (A2), by the analogue portion, depending on the current parameters of the plurality of analogue primitives, of time information (IT) from the input signals (Sig.E) and/or of frequency information (IF) from these same signals; the latter may correspond to a plurality of moments of the signals of the learning database;
Construction (A3), using the previously extracted time and/or frequency information, of an intermediate data structure (SDI), formed for example by the juxtaposition of the information extracted by the analogue portion from the signals of the learning database; the structure can be a tensor.
Classification (A4), by the digital portion, depending on the current parameters of the plurality of digital primitives (PC), and from the intermediate data structure (SDI), of the plurality of events detected by the analogue part, delivering a plurality of portions of classified signals (PSC);
Calculation (A5), from the plurality of portions of classified signals, of a classification error rate (Err);
Correction (A6) of the current parameters of the plurality of parameterisable analogue primitives and of the plurality of parameterisable digital primitives depending on the error rate (Err). The learning presented in relation to FIG. 22 is exemplified by the following explanations. A starting point is a one-dimensional signal as shown in FIG. 4. The input signal can also be multi-channel. For the present description a single-channel signal is used. First, this signal is manually labelled as shown in FIG. 5. The labels define the targets to be detected in the input signal. This conventional manual labelling operation is performed for all signals constituting the learning database. Once the database is labelled, the training of the primitive network begins.

The labelled data are provided as input to the primitive network and the analogue portion performs the first step of the processing for the extraction of the moments of the signals. This analogue portion also generates an intermediate data structure which constitutes the input of the digital portion as shown in FIG. 6. This intermediate data structure is automatically labelled according to the current parameters of the analogue primitives. However, given that it is not (yet) optimised, it can lead to extracting information with non-optimal relevance. Then the digital portion performs a classification of the data extracted by the analogue portion and, in learning, it is therefore possible to calculate the error of the system (of the circuit as a whole) from the true and false detections according to the labels of the initial database.

Having calculated the error (that is to say the number of erroneous detections relative to the number of detections to be assigned), an optimised backpropagation method is used to adjust the parameters (weight and bias) of the analogue and digital portions using the gradient backpropagation algorithm (gradient backpropagation). In this situation, it is therefore necessary to calculate the derivative of the error relative to each of the parameters of all primitives, as in the case of a conventional neural network, in order to be able to adjust these parameters of all primitives using a learning rate hyperparameter.

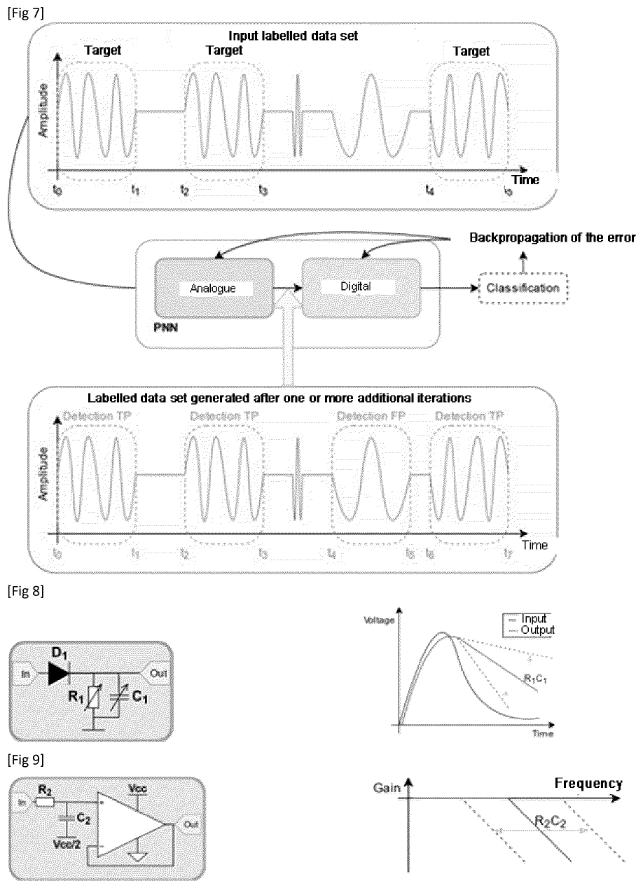

This cycle represents an iteration (an epoch) of the learning: generation of a self-labelled training set at the output of the analogue part, then optimisation of the digital part on this self-labelled training set, then optimisation of the analogue part to minimise the overall error. In the following iteration, the parameters of the analogue and digital parts have already been adjusted once so the error starts to decrease from the second iteration. Consequently, the first step of the analogue processing of the second iteration already filters events that are not part of the target as exemplified in FIG. 7.

This learning method allows the optimisation of the entire primitive network (analogue portion and digital portion) and also allows calculating an index of detection accuracy versus energy consumption since depending on the complexity of the primitive network, the detection accuracy, but also its energy consumption are increased.

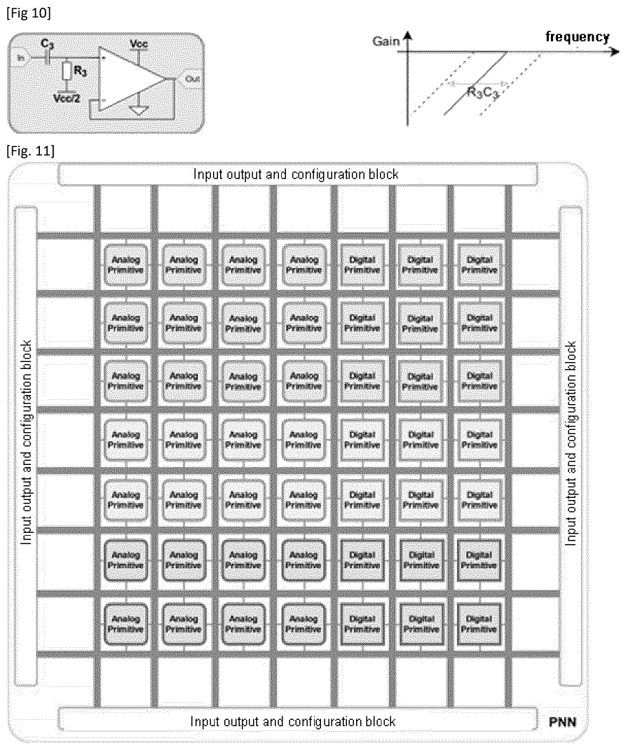

Thus, the primitives of the primitive network consist of circuits and operators whose parameters are learned during training from a labelled database. Among the existing primitives, the following primitives exemplified:
Analog peak detector: this primitive can be implemented with a diode, a resistor and a capacitor as shown in FIG. 8 (left). This primitive is key for the detection of transients as shown in FIG. 8 (right). It can also be used after a bandpass filter to detect the energy level in the frequency band. The parameter to be learned during the learning phase is the constant: Tau (R₁C₁).
Analog filters: these primitives can be implemented with one or more operational amplifiers, resistors and capacitors as shown in FIG. 9 (left) and FIG. 10 (left). They allow selecting the frequency bands of interest, as shown in FIG. 9 (right) and FIG. 10 (right). They can also be used to calculate the average value of a signal, in the case of a low-pass filter. The parameters to be learned during training are the cut-off frequencies, in FIGS. 9 and 10 a low-pass filter primitive and a high-pass filter primitive are shown, where the cut-off frequencies are defined by R₂C₂ and R₃C₃ respectively.
Analog correlator relative to a parameterisable pattern (pre-established or that can evolve over time) such as a wavelet or between different channels of input signals.
Analog delay: allows temporally shifting the input signal with a constant, but adjustable delay in a limited frequency band.
Integrator: this primitive allows integrating the input signal and amplifying the result.
Derivator: this primitive allows deriving the input signal and amplifying the result.
Digital filters: these primitives allow, in the same manner as the analogue filters, selecting the desired frequency band. However, they are implemented in digital form, and this makes them interesting for processing low frequency signals (which are low energy consumers in digital).
Digital neuron: this primitive is the conventional neuron. It can be used alone or grouped on a neural network in the last layers of a network of primitives. The parameters to be learned are conventionally the weights and biases.
Digital Fast Fourier Transform (FFT): this primitive allows extracting the frequency features of a signal from their temporal evolution.
State machine: implements sequential signal processing mechanisms, which allows for example implementing expert rules that can be parameterised.

### Example of Implementation of the Primitive Network

The primitive network architecture couples digital and analogue primitives. The digital part can be implemented in the form of an FPGA (field-programmable gate array), in a microcontroller as illustrated in FIG. 11 or in a dedicated silicon circuit. The architecture of the analogue part of the primitive network requires a form of ultra-low-power oriented mixed FPAA (Field programmable analogue array). The FPAA is the analogue equivalent of the FPGA. Unlike FPGAs, FPAA circuits contain a more limited number of configurable blocks CAB (“Configurable Analog Blocks”).

The use of analogue and digital primitives allows considering different types of signal processing having a very different frequency spectrum. Analogue processing mainly targets high bandwidth signals because the potential gain in energy consumption is then two orders of magnitude (factor 100), while digital processing, more versatile, targets in turn more conventional classification operations using neural networks. In order to further optimise consumption, among the analogue primitives, several operational amplifiers can be implemented with different “gain-bandwidth” products and are used according to the frequency of the signals to be processed. This is represented in FIG. 11 with three types of analogue and digital primitives (Analogue primitive/Digital Primitive). All these primitives can be turned off to minimise the energy consumption.

In other words, there is again a mixed analogue/digital architecture, which is neither quite an FPGA nor quite an FPAA. This architecture allows configuring both the digital primitives and the analogue primitives, by loading them with the parameters learned during learning. These parameters are provided to each configurable block during a configuration phase after the learning phase, as previously presented.

### Description of an Exemplary Embodiment of the Learning Method

As previously exposed, the method of learning the parameters of such a primitive network is modified relative to the conventional learning methods implemented for digital neural networks. As exposed in general, this method comprises a double optimisation: optimisation of the digital parameters and optimisation of the analogue parameters. Below is an exemplary embodiment of such a mixed learning method. More particularly, the focus is on the methodology for adjusting the parameters as iterations are performed. This methodology is inspired by the conventional backpropagation algorithm. However, when temporal primitives (such as filters) are used, it is no longer possible to apply the derivative of the output relative to the parameters or weights to be learned to minimise the error. It is for this reason in particular that a new learning method is proposed.

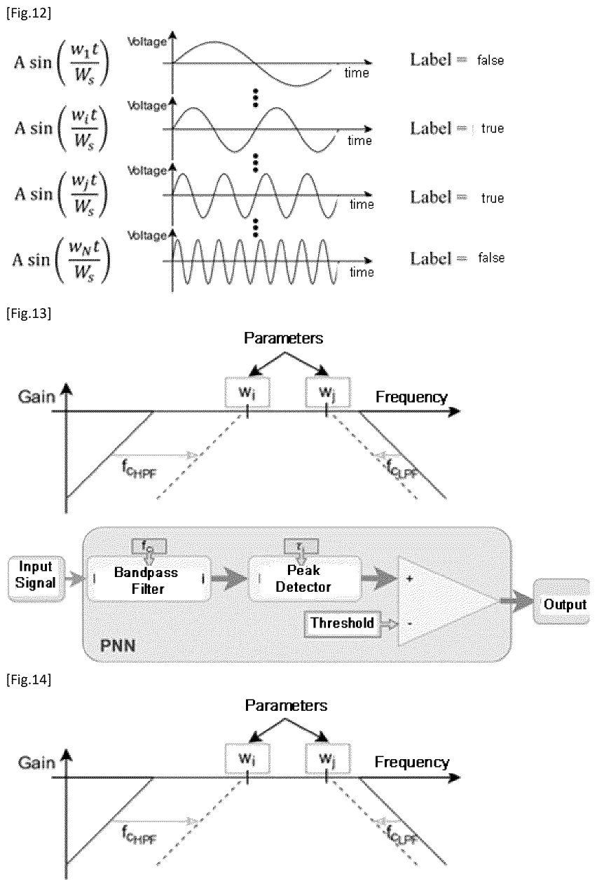

This new method was implemented in simulation for learning parameters from a labelled database, the objective being to automatically learn the parameters of the analogue primitives, together with the digital parameters, from a single initial labelling. In this example, the learning of a simplified analogue stage is therefore only presented. Digital learning is not illustrated here, as it is otherwise conventional). First, as previously indicated, a database was generated. It is composed of a large number of samples, each comprising a sinusoidal signal with a constant amplitude equal to 1V but whose frequencies vary from 10 to 180 Hz. The sampling frequency is in turn set to 400 Hz. The database is partially illustrated in FIG. 12 (database of input signals and corresponding label). As illustrated, different labels were used to test the convergence of the model. They were generated by an algorithm. As can be seen, this database describes a bandpass filter centred at

$$\frac{wi + wj}{2}$$

with a bandwidth equal to |wj−wi|.

After the generation of the database, a network structure of primitives was proposed for learning the parameters of the primitives. This primitive network is shown in FIG. 13 and is composed of three primitives:
A band-pass filter: this filter is composed of a high-pass filter coupled with a low-pass filter. Their cut-off frequencies are f_{cHPF} and f_{cLPF}, which must be learned during training;
A peak detector: this primitive is composed of a diode and a low-pass filter to maintain the voltage level for a period of time defined by ti, which must be learned during training, but which, at first, is fixed to describe more simply the learning method;
A comparator: this primitive generates a high logic level when the voltage in the positive input corresponding to the voltage level at the output of the peak detector (and therefore to the energy of the signal in the bandwidth of the filter) is higher than that of the negative input (reference set at first, but optimised by learning). Based on this architecture of the primitive network, the parameters are initialised as follows:
f_{cHPF} and f_{cLPF} are the two parameters to be learned. At the end of the training they will converge to the frequencies that will define the central frequency of the bandpass filter f_{ci} and the bandwidth thereof.

Therefore, the first frequency is initialised to:

$$fcHPF = \frac{fSampling}{2} {Spectrum}_{Percentage}$$

the second frequency is initialised to

$$fcLPF = \frac{fSampling}{2} ( 1 - {Spectrum}_{Percentage} )$$

SpectrumPercentage is a hyperparameter to be defined as the learning rate and in this case it is equal to 0.05. Which makes the initial values of f_{cHPF} and f_{cLPF} equal to 10 and 190 Hz respectively, since f_{Sampling} is equal to 400 Hz.
τᵢ is preset to make the training faster. It is equal to 250 ms the value of the temporal length of each of the samples of the database to be able to maintain the voltage level until the end.
Threshold is also preset to simplify the training. It is equal to 0.7V since the amplitude of the sinuses of the database is equal to 1V.

The first iteration of training begins after the initialisation of the parameters of the primitive network. The objective of the successive iterations is to converge to the frequencies labelled in the database, as illustrated in FIG. 14. In this training, the derivative of the error of the primitive network after processing the database relative to each frequency (f_{cHPF} and f_{cLPF}) must be calculated. This primitive of the bandpass filter type has a kind of memory relative to the input at time i₁. For the simulation, the filters implemented are of first order, this memory demonstrates that it is necessary to modify the training method to be compatible with temporal primitives such as filters.

Thus, the training is carried out as follows:
First, each sample of the database is filtered and the output of the comparator is compared to the desired labelling (true or false detection).
Then, after presenting the complete training base, the global error of the primitive network, Error f_{cHPF}-f_{cLPF} is obtained by comparing the obtained labels and detections.
From this error calculation, the cut-off frequency of the high-pass filter is updated using eq. 1. Where Derivate_{Percentage} is a hyper parameter to be preset as the learning rate. In this case it is equal to 0.1.

$$fcHPF + Δ f = fcHPF + \frac{fSampling}{2} {Derivate}_{Porcentage}$$

After updating the high-pass filter cut-off frequency, the database is presented again to determine the new global error: Error_{fc+Δf-fcLPF} and to be able to calculate the derivative of this error as a function of the variation of f_{cHPF} as shown in the following eq. 2:

$$\frac{Δ Error}{Δ fcHPF} = \frac{ErrorfcHPF\_fcLPF - ErrorfcHPF + Δf\_fcLPF}{\frac{fSampling}{2} {Derivate}_{Porcentage}}$$

After calculating the first derivative of the error, f_{cHPF} is reset to its previous value and the same method is applied to calculate the derivative relative to f_{cLPF}, in order to obtain

$$\frac{Δ Error}{Δ fcLPF}$$

Finally after calculating all derivatives, the gradient of the global error relative to the analogue parameters is determined and allows the update of the cut-off frequencies of the filters with eq. 3 and eq. 4.

$$fcHPF = fcHPF + LearningRate \cdot \frac{Δ Error}{Δ fcHPF} \qquad ( 3 )$$

$$fcLPF = fcLPF + LearningRate \cdot \frac{Δ Error}{Δ fcLPF} \qquad ( 4 )$$

This cycle representing an iteration is then repeated until convergence or until reaching the defined number of iterations. This method can be used for primitives whose output depends on the input at time i as well as at previous times. In the case of a multiplier or comparator for example, the output depends only on the current input and therefore this simplifies learning.

In this manner, learning is implemented, the frequencies of the bandpass filter are learned from the database by a gradient descent algorithm, even if it is not formally calculable, not allowing the use of a backpropagation type algorithm. The drawback of this method is that for each iteration, the complete database must be processed several times, a drawback offset by the use of the mini batch technique. The method is also sensitive to the adjustment of the hyperparameters of the model, at the risk of not converging. The most important are SpectrumPercentage for the initialisation of the frequencies and the Derivate_{Percentage} to calculate the derivatives. The results obtained for this network of primitives are however very good.

### Description of an Application Example

A case of application of the primitive network architecture concerning the detection of leaks on an oil installation is presented. The first step is the generation of a database using an analogue sensor coupled to a recorder installed on site. Several operating modes were recorded to enrich this database and to be able to distinguish between correct operating modes and faults. For this, the database was labelled with the different classes to be identified in the second step. The third step consists in processing the data in analogue form to obtain an intermediate data structure also labelled but dependent on the analogue circuit for preprocessing. This intermediate data structure is used to train the algorithms of the digital portion, for example the convolutional neural networks. Therefore, in the fourth step, the training is carried out and the results of the classification, in particular the ROC curve, are evaluated to modify the parameters of the analogue portion and obtain the optimal configuration. These last two steps are iterated until the convergence of the system is obtained if it occurs. These different steps are detailed below.

### Step 1: Generation of the Database

The first step consists in recovering data from the corresponding sensors for the detection of the desired events. This step is the most important since the reliability of the primitive network depends mainly on the richness of the database on which the learning is performed. In the application case, a pressure sensor was used to measure the behaviours of an oil installation with and without defects. Therefore, the aim is to identify these behaviours and notify the case of found defects. The data in this case are one-dimensional, the pressure is recorded over time. These data are recorded in a predefined format to be able to label them in the next step.

### Step 2: Labelling of the Database

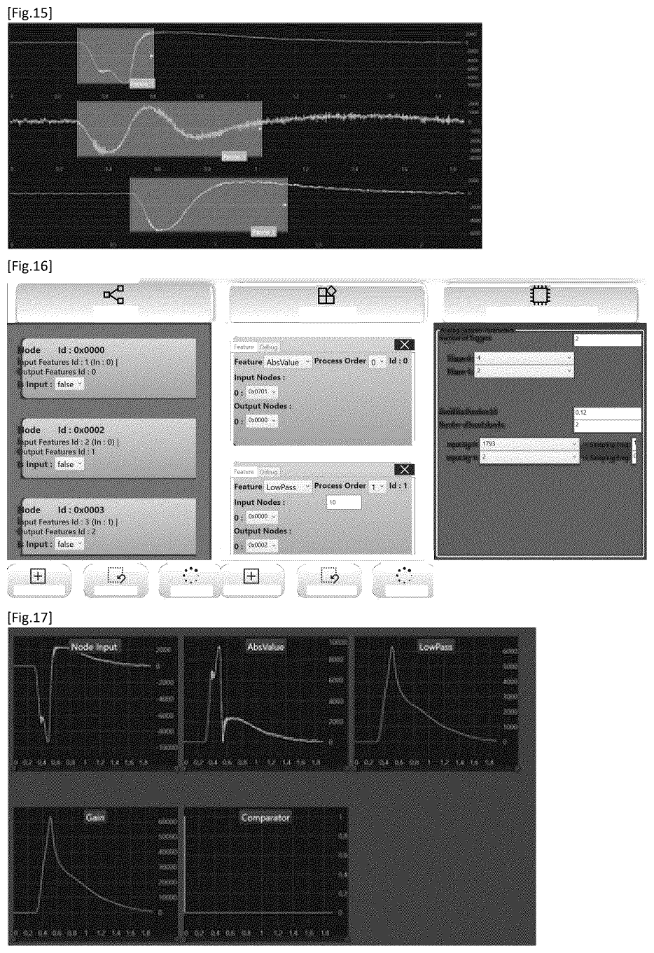

After having obtained a database, it must be labelled. In FIG. 15, three examples of the labelled raw data from the pressure sensor are shown. It is important that the data are labelled in the precise moments when the events occur because they are processed in analogue form and not directly with a convolutional neural network (which takes the complete sample as input).

These samples constitute the input of the primitive network which, with the analogue blocks it contains, generates the intermediate data structure labelled automatically from those defined on the basic signals. This intermediate data structure constitutes the input of the algorithms implemented in digital form.

### Step 3: Analogue Processing and Learning.

After labelling the data, a primitive network is predefined for the analogue processing which leads to obtaining the intermediate database. This primitive network is, in this example, illustrated in FIG. 16. The analogue primitives are defined and connected to each other according to the characteristics of the database knowing that several sensors can be used and processed in parallel.

At the output of the analogue part, intermediate data are generated from the output values of the analogue primitives, and are used for training the digital portion, while retaining their initial labelling. Trigger nodes can be defined to wake up the digital portion and perform an analysis on the analogue data at a time when an interesting phenomenon is suspected to occur.

In FIG. 17, the outputs of several primitives are shown. The first graph “node input” shows the labelled raw data from the sensor, then the second “AbsValue” shows the output of the first primitive that performs an absolute value of the input. The third graph illustrates the output of a low-pass filter, this is the second primitive whose cut-off frequency must be learned and is connected to the output of the first primitive. Finally, we find the last two primitives and the graphs thereof, “gain”, an amplifier and “comparator” a comparator that compares the output of the amplifier with a voltage level to be learned.

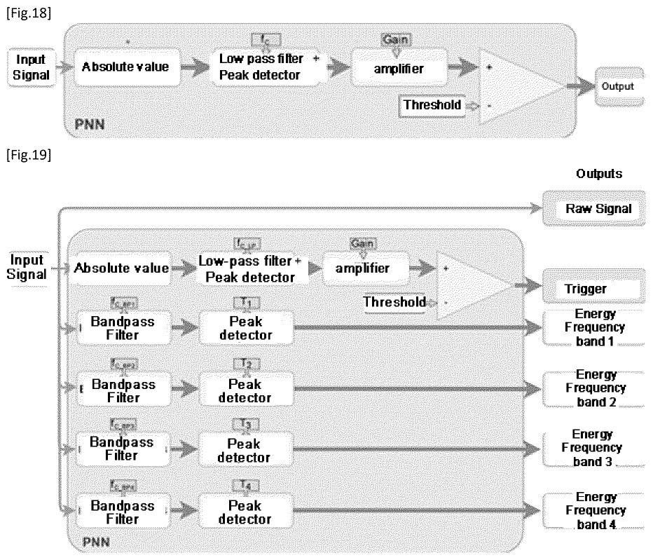

In this case the simplified analogue stage of the implemented primitive network is shown in FIG. 18. This stage of the primitive network wakes up (activates) the digital stage of the primitive network at each rising edge of the comparator output and triggers an analysis to confirm if it is a true positive. Consequently, a trigger node and a tensor generation node are defined.

The used complete primitive network is shown in FIG. 19, this schematic has four parallel channels independent of the main channel responsible for triggering from a transient. These four channels have a bandpass filter and a peak detector which are used to continuously measure the energy in the different frequency bands.

When the comparator is triggered by the presence of a peak in the signal that could correspond to a desired signal, the raw signal is acquired at 100 [Hz] for a defined time (here one second) and a second acquisition of the raw signal is performed at 1 [KHz] for 0.1 second (one tenth of a second) offset by two (2) seconds after the trigger to measure the noise level. The digital stage is responsible for making the acquisitions but remains in deep sleep mode most of the time. Only the ultra-low power analogue part of the primitive network will remain in “always on” mode. The four bandpass filters of this stage allow storing information on the past to enrich the analysis performed on the digital stage with the frequency distribution corresponding to times located before the trigger. These four energy level outputs on the different bands are sampled a second time with a predefined delay to have comparison data on the evolution of the frequency composition of the signal around the trigger. These are (significant) indicators on the signal to be taken into account for the subsequent analysis.

In this manner, the information of the raw signal allows the detection of the shocks and the spectral information of the energy levels on the four frequency bands after the event allows the frequency characterisation of the signal before and during the phenomenon to be analysed, a bit like an FFT would do (but without the need to carry out such an energy-intensive FFT in digital). The combination of these two information items delivers a tensor: a frequency and time signature of the event to be analysed. All this processing is performed in ultra-low consumption mode since the digital stage is on standby most of the time and the analogue stage is designed to achieve a minimal consumption.

As previously explained, the learning of the weights of the analogue stage is performed by iterations after joint optimisation of the digital stage.

Étape 4: Digital Processing and Learning.

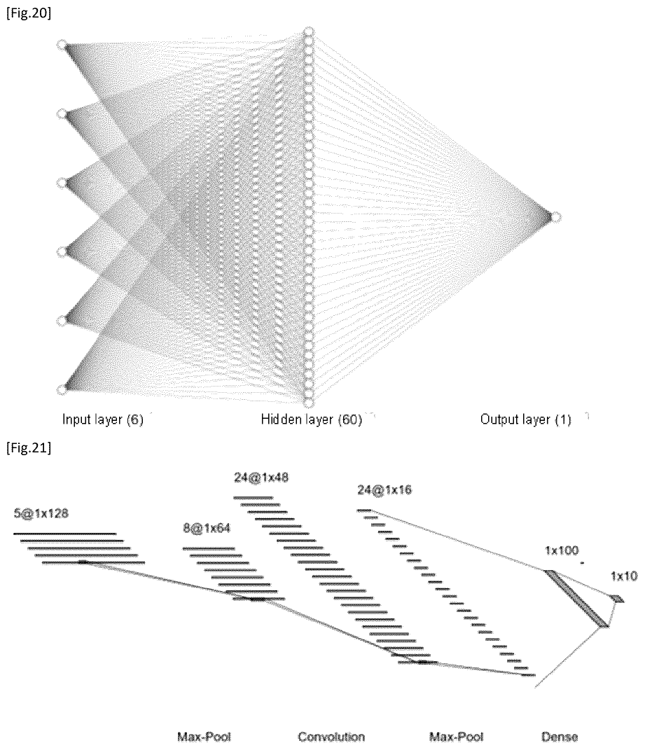

The digital stage of the primitive network learns from the intermediate data structure generated by the analogue stage and can be presented in the form of an expert system, a shallow conventional neural network as shown in FIG. 20 or a convolutional neural network as shown in FIG. 21. The digital algorithm to be implemented depends mainly on the difficulty of the problem to be solved and the targeted energy consumption.

### Step 5: Evaluation of the System.

The system is evaluated and learned from the indicators on the detection rates (true positives TP, false positives FP, true negatives TN and false negatives FN), and therefore depending on the initial labelling of the data for learning. These indicators allow adjusting the coefficients of the analogue stage during training as well as in real time in dynamics. For example the detection threshold of the comparator: when there is a very noisy signal, many false positives are generated therefore the threshold of the comparator can be increased to reduce the number of false positives when there is noise.

### Step 6: Integration and Deployment.

The final step consists in loading the learned parameters and models into the analogue/digital primitive network in production mode. The advantage of such an implementation consists in, on the one hand, having an efficient circuit requiring low energy consumption, whose parameters can be updated depending on the evolution of the signals for example, and which can also be used in other use cases than that described in the present example.

1. A method implemented by a computer or a data processor, the method comprising:
determining implementation parameters of an electronic circuit, said electronic circuit being configured to process an input signal, the electronic circuit comprising an analogue portion comprising a plurality of parameterisable analogue primitives and a digital portion comprising a plurality of parameterisable digital primitives, the implementation parameters of the electronic circuit including parameters of the plurality of parameterisable analogue primitives and parameters of the plurality of parameterisable digital primitives, the digital portion being coupled to the analogue portion via at least one analogue-digital converter and/or at least one analogue comparator with or without hysteresis, said determining comprising:
a phase of learning said parameters of the plurality of parameterisable analogue primitives and said parameters of the plurality of parameterisable digital primitives, said learning phase being joint with the parameters of the plurality of parameterisable analogue primitives and with the parameters of the plurality of parameterisable digital primitives.

2. The method according to claim 1, wherein the learning phase comprises at least one iteration of the following steps, performed using a labelled signal learning database:
loading of the current parameters of the plurality of parameterisable analogue primitives and the plurality of parameterisable digital primitives;
extraction, by the analogue portion, depending on the current parameters of the plurality of analogue primitives, of time information from the input signals and/or of frequency information from these same input signals, this information being able to correspond to a plurality of moments of the input signals of the learning database;
construction using the previously extracted time and/or frequency information, of an intermediate data structure;
classification, by the digital portion, depending on the current parameters of the plurality of digital primitives, and from the intermediate data structure, of the plurality of detected events, delivering a plurality of portions of classified signals;
calculation, from the plurality of portions of classified signals, of a classification error rate;
correction of the current parameters of the plurality of parameterisable analogue primitives and of the plurality of parameterisable digital primitives depending on the error rate.

3. The method according to claim 1, wherein the learning phase ends when the classification error rate is lower than a predetermined threshold and/or when a target power consumption, in operational operation, of said electronic circuit is reached.

4. The method according to claim 2, wherein the learning phase comprises correcting the current parameters of the plurality of parameterisable analogue primitives and the plurality of parameterisable digital primitives, which comprises at least one iteration of the following optimisation sequence: optimisation of the digital portion by backpropagation, then optimisation of the analogue portion.

5. The method according to claim 1, wherein the digital portion comprises at least one neural network adapted to classify the signals received via analogue-digital converters and the parameters of the plurality of parameterisable digital primitives comprise at least weights and biases of said neural network.

6. The method according to claim 1, wherein the digital portion is, by default, on standby.

7. The method according to claim 1, wherein the analogue portion comprises at least one band-pass filter, said band-pass filter allowing identifying frequencies of interest, and the parameters of the plurality of parameterisable analogue primitives comprise at least cut-off frequencies of said band-pass filter, and the analogue portion comprises a plurality of trigger nodes for waking up said digital portion based on an identification of said frequencies of interest.

8. An electronic circuit comprising:
an analogue portion and a digital portion, the digital portion being coupled to the analogue portion via at least one analogue-digital converter, and/or at least one analogue comparator with or without hysteresis, the analogue portion comprising a plurality of analogue primitives parameterised according to a first set of parameters and the digital portion comprising a plurality of digital primitives parameterised according to a second set of parameters, said first and said second sets of parameters belonging to implementation parameters of said electronic circuit, said first and said second sets having been subjects of joint learning; and
a computer or a data processor configured to determine the implementation parameters of the electronic circuit, the determining comprising:
a phase of learning said parameters of the plurality of parameterisable analogue primitives and said parameters of the plurality of parameterisable digital primitives, said learning phase being joint with the parameters of the plurality of parameterisable analogue primitives and with the parameters of the plurality of parameterisable digital primitives.

9. The electronic circuit according to claim 8, wherein the plurality of parameterisable analogue primitives comprises analogue primitives which belong to the group consisting of: passive and/or active filters, envelope detectors, multipliers, operational amplifier assemblies, diodes, analogue convolutions, integrators, derivators, delay.

10. The electronic circuit according to claim 8, wherein the analogue portion of the electronic circuit is divided into a first part, called signal preprocessing part and a second part called moment extraction part, an output of the signal preprocessing part being connected to an input of the moment extraction part, an output of the moment extraction part being directly connected to the digital portion using the at least one analogue-digital converter and/or the at least one analogue comparator.

11. The method according to claim 1, the method further comprising: loading the first and second sets of parameters having been the subject of joint learning.

12. A non-transitory computer readable medium comprising a computer program product stored thereon and program code instructions for executing the method according to claim 1, when the program code instructions are executed by the computer or the data processor.
